(19) United States
(12) Patent Application Publication
(10) Pub. No.: US 2026/0063705 A1
(43) Pub. Date: Mar. 5, 2026

(54) FULLY INTEGRATED PROCESS MONITOR AND THRESHOLD VOLTAGE EXTRACTOR CIRCUIT

(71) Applicant: Bar-Ilan University, Ramat Gan (IL)

(72) Inventors: Joseph Shor, Tel Mond (IL); Ido Shpernat, Kiryat Ono (IL); Asaf Feldman, Karmiel (IL)

(73) Assignee: Bar-Ilan University, Ramat Gan (IL)

(21) Appl. No.: 19/315,576

(22) Filed: Aug. 31, 2025

Related U.S. Application Data
(60) Provisional application No. 63/690,814, filed on Sep. 5, 2024.

(51) Int. Cl. G01R 31/28; H03M 3/00

(52) U.S. Cl. CPC G01R 31/2856; G01R 31/2879; H03M 3/43; H03M 3/464

(57) ABSTRACT

A new architecture of an on-die process monitor circuit is described, without limitation, in 28 nm. The circuit can extract the threshold voltage, V_{TH}, and random mismatch of a transistor using multiple extraction methods, such as but not limited to, the second derivative method. A sigma-delta modulator analog-to-digital converter may sample the output to enable on-die processing of the results. A V_{DS} voltage control loop may be used to enable V_{TH} extraction in both the linear and saturation regions of the device. The circuit may have a compact area of 5510 μm².

### FIELD OF THE INVENTION

The present invention relates generally to transistor circuitry, which can generate precise I-V (current-voltage) curves of transistor devices and accurately extract threshold voltage (V_{TH}) (both in the linear and saturation regions), and local mismatch.

### BACKGROUND OF THE INVENTION

Energy efficiency requirements have driven low voltage near-V_{TH} computing applications, which improve the power performance tradeoff for many workloads [1]. When the device operates near V_{TH} (threshold voltage), in the sub-threshold region, its current varies exponentially with the gate-source (V_{GS}) voltage and can drift significantly with any on die and process variations. Variation of an operational parameter of the transistor device due to die or process or other variations is referred to as random variation. To account for these shifts, process parameters are measured intensively prior to high volume manufacturing (HVM). In addition, some systems integrate basic parameter extraction circuits such as delay lines or ring oscillators which can help characterize the Si prior to HVM or even as part of steady state operation in real time [2]. Some circuits extract V_{TH} by generating a reference voltage of V_{TH} at OK [3], [4] or an output voltage which is equal to V_{TH} across temperature [5]. However, in most HVM cases the V_{TH} extraction methods are done in scribe lines off chip. It would be desirable to have an on-die compact process monitor (PM) to measure different device V_{TH} and local mismatch, at different locations in the product. This would benefit Dynamic Voltage Scaling (DVS) applications with real-time V_{TH} measurements, which could be done occasionally.

V_{TH} varies between the device linear region (V_{TH,LIN}) or in saturation (V_{TH,SAT}) [6]. V_{TH,LIN} measurements are relevant for digital circuits, whereas V_{TH,SAT} measurements are needed for both analog and digital circuits. It is thus desirable for the PM to be able to extract both. There are multiple methods to estimate these V_{TH} values [6]. The constant current (CC) method is a rather simple technique which measures the V_{GS} of a device which drives 0.1-5 μA per leg. Its simplicity stems from the single measurement of V_{GS} required at the target current. This method was demonstrated in [7] on multiple device types and generating a digital code representing V_{TH}.

However, in [7] only diode connected devices were measured, enabling extraction of V_{TH,SAT} only. In addition, [6] suggests that to accurately extract V_{TH} in both linear and saturation regions the current should be adjusted, which is not possible in [7]. More accurate methods such as linear extrapolation (LE) [8], gm/ID, second and third derivatives (SD, TD) exist, but these require an I-V curve of the tested device [6] which was not possible in [7]. The more accurate methods observe the inflection points of the I-V curve marking a transition between sub-threshold and strong inversion of the device and accurately detecting that point as V_{TH}. In addition, scanning the current to measure this inflection point can reduce variations in the auxiliary circuits surrounding the tested device. FIG. 1 shows a measured extraction of V_{TH} using the SD (second derivative) method. The maximum of the second derivative curve is the transition point from subthreshold to the strong inversion (marked with the blue arrow) [6].

In most cases the precise methods test a large device in a standalone environment. Measuring V_{TH} and other device parameters in a real SoC (system on chip) would be highly desirable for process engineers to see how the fabrication models are applied in real applications and after dicing and packaging. The process parameters would also be visible to the product developers (from whom they are usually hidden). The present invention describes a fully integrated process monitor (PM), without limitation, in 28 nm, which can generate precise I-V curves of NMOS (n-type metal oxide semiconductor) and PMOS (p-type metal oxide semiconductor) devices and accurately extract V_{TH} (both in the linear and saturation regions), and local mismatch with any of the above techniques.

### SUMMARY OF THE INVENTION

The present invention seeks to provide a process monitor which can generate precise I-V (current-voltage) curves of transistor devices and accurately extract threshold voltage (V_{TH}) (both in the linear and saturation regions), and local mismatch, as is described more in detail hereinbelow.

There is provided in accordance with a non-limiting embodiment of the invention, a process monitor for a transistor device including a current source circuitry configured to provide an input current (IN) to a drain of an NMOS (n-type metal oxide semiconductor) or PMOS (n-type metal oxide semiconductor) Device Under Test (DUT), a drain-source voltage regulation circuitry configured to regulate a drain-source voltage (referred to as V_{DS} for NMOS, V_{SD} for PMOS) of the DUT, a gate-source voltage regulation circuitry configured to regulate a gate-source voltage (V_{GS}) of the DUT versus the input current so that the drain-source voltage remains constant and the DUT is in a linear region or in a saturation region or between the linear and saturation regions, and a measurement circuitry configured to measure the gate-source voltage to derive therefrom an operational parameter of the transistor device.

In accordance with a non-limiting embodiment of the invention the operational parameter is a threshold voltage of the DUT, which could be in the linear or saturation region or in-between, or a mobility of a silicon substrate of the DUT, or a random variation of the DUT.

In accordance with a non-limiting embodiment of the invention the current source circuitry includes a switched capacitor circuit.

In accordance with a non-limiting embodiment of the invention the switched capacitor circuit includes a reference voltage which is applied to at least one switching capacitor to generate the input current which equals C*V*F, where C is capacitance of the at least one switching capacitor, V is the reference voltage and F is a switching frequency, and the input current is mirrored to the DUT.

In accordance with a non-limiting embodiment of the invention the current source circuitry is configured to vary the input current by changing a clock frequency and a core capacitance in the switched capacitor circuit.

In accordance with a non-limiting embodiment of the invention there is more than one DUT, and a multiplexer is provided which is configured to select which DUT is to be measured from the more than one DUT.

In accordance with a non-limiting embodiment of the invention the gate-source voltage is forwarded to a discrete-time sigma-delta modulator (DT-SDM) analog-to-digital converter.

### BRIEF DESCRIPTION OF THE DRAWINGS

The present invention will be understood and appreciated more fully from the following detailed description, taken in conjunction with the drawing in which:

FIG. 1 is a simplified graphical illustration of a prior art method for extracting the threshold voltage with the second derivative method.

FIG. 2 is a simplified illustration of block diagram of the process monitor (PM), in accordance with a non-limiting embodiment of the present invention.

FIG. 3 is a simplified illustration of different devices under test used in the PM of the present invention. NMOS and PMOS stacks were used where the stack count is five and all devices in the stack have a multiplier of 20.

FIG. 4A is a simplified illustration of a PM mode for measuring NMOS devices under test (DUTs), wherein there are three feedback loops that regulate the DUT to extract V_{TH}, in accordance with a non-limiting embodiment of the present invention.

FIG. 4B is a simplified illustration of a PM mode for measuring PMOS devices under test (DUTs), wherein there are three feedback loops that regulate the DUT to extract V_{TH}, in accordance with a non-limiting embodiment of the present invention.

FIG. 5 is a simplified illustration of varying I_{DUT} (the current input to the DUT) by changing the clock frequency and by varying the core capacitance in a SCR (switched-capacitor resistor), in accordance with a non-limiting embodiment of the present invention.

FIG. 6 is a simplified illustration of a discrete-time sigma-delta modulator (DT-SDM) analog-to-digital converter (ADC) used in an embodiment of the invention.

FIG. 7 is a simplified illustration of the PM fabricated in a 28 nm CMOS process.

FIG. 8A is a simplified illustration of a simulated V_{TH,LIN} of the NMOS stack using the second derivative (SD) method for five corners.

FIG. 8B is a simplified illustration of Monte Carlo (MC) simulations of the DUTs with an idealized PM, as well the PM circuit with the DUT excluded from the simulation.

FIG. 9 is a simplified illustration of a polynomial fit of the measured I-V curves extracted from the V_{GS} measurements of the NMOS stacked DUTs in the linear region of one chip.

FIG. 10 is a simplified illustration of both simulated and measured V_{TH} using the CC method for nominal and stacked NMOS DUTs when sweeping V_{DS}.

FIG. 11 is a simplified illustration of repeated room temperature measurements of V_{TH,LIN} of the NMOS Stack DUT using SD in four PMs, showing repeatability of 1 LSB (least significant bit) (1 mV).

FIG. 12 is a simplified illustration of an SD measurement of V_{TH,LIN} versus temperature for all DUT types.

FIG. 13 is a simplified illustration of the measured and simulated V_{TH,LIN} versus temperature using the CC method of the stacked NMOS DUT.

FIG. 14 is a simplified illustration of room temperature measurement of V_{TH,LIN} and V_{TH,SAT} of NMOS stacks using CC and SD methods on three chips.

FIG. 15A is a simplified illustration of the measured mismatch of V_{TH,LIN} for 128 nominal NMOS devices using the SD method at room temperature.

FIG. 15B is a simplified illustration of V_{TH,LIN} of the nominal NMOS of a single chip (32 DUTs) vs. temperature.

### DETAILED DESCRIPTION OF EMBODIMENTS

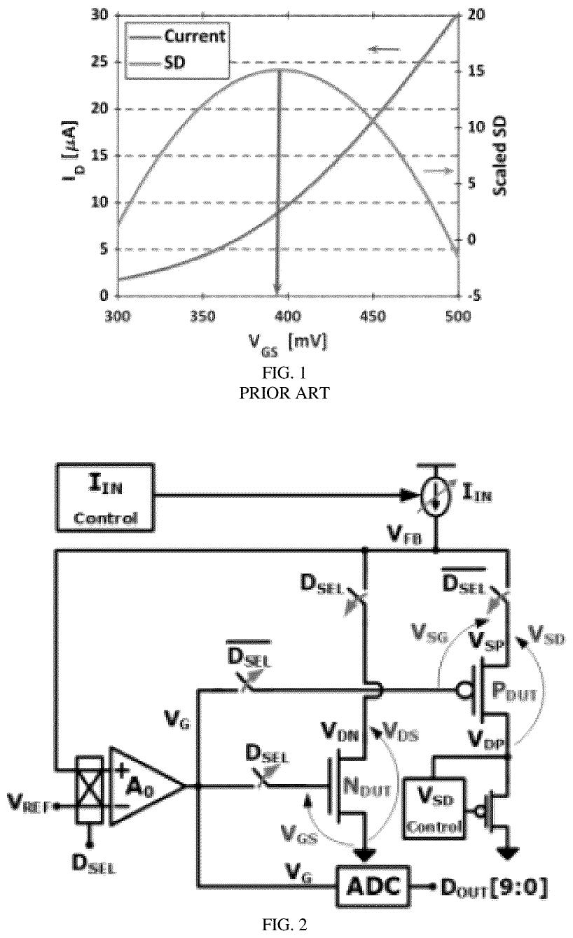

Reference is now made to FIG. 2, which illustrates a block diagram of the process monitor (PM), in accordance with a non-limiting embodiment of the present invention.

A variable current source drives a current I_{IN} to an NMOS or PMOS Device Under Test (DUT) which is digitally selected by the D_{SEL} signal of a multiplexer circuit. The gate of the DUT (V_{G}) is set by the amplifier A₀ based on I_{IN} and by equalizing V_{FB} (feedback voltage) and V_{REF}. For the NMOS DUT V_{FB}=V_{REF} is the drain-source voltage (V_{DS}) and in this manner the gate-source voltage (V_{GS}) is swept versus the input current at a constant V_{DS} which places the devices either in the linear or saturation region based on V_{REF}. V_{G} is sampled by the ADC for the I-V curve generation. For the PMOS configuration V_{FB} is the source of the DUT so an additional regulation sets VDP (drain voltage of the PMOS) and thus V_{SD} (source-drain voltage) of the PMOS.

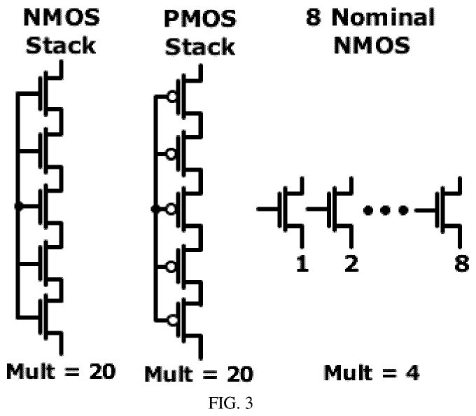

FIG. 3 shows the different DUTs used in the PM. NMOS and PMOS stacks were used where the stack count is five and all devices in the stack have a multiplier of 20. Furthermore, 8 nominal NMOS devices, each with a multiplier of 4, were added to measure random variation. All the transistor legs in the stacks and nominal devices have a W/L of 100n/30n. The DUTs of the stack have a small variation, so they would predict the process corner, while measuring several nominal DUTs would characterize the random variation. A multiplier of 4 was used in the nominal devices to preserve similar current densities in the DUTs. Finally, using stacked structures allows for measurement of the analog characteristics of the devices, since stacks are used in analog circuits, especially in a FinFET (Fin Field Effect Transistor) process.

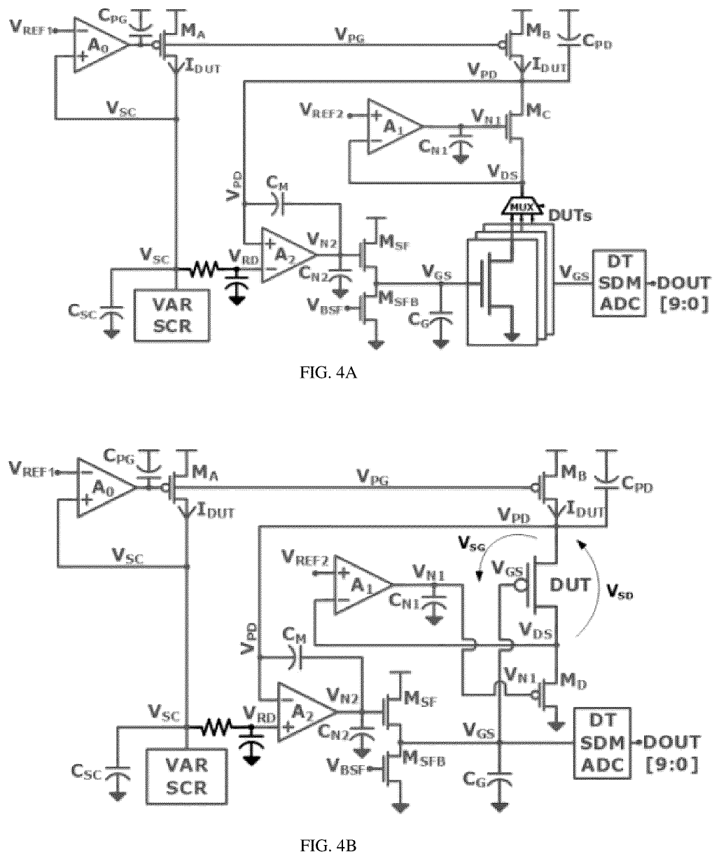

The PM mode for measuring the NMOS DUTs (D_{SEL}=1 in FIG. 2) is depicted in FIG. 4A. There are three feedback loops that regulate the DUT to extract V_{TH}. The first loop, controlled by amplifier A₀ (green), generates a precise current (I_{DUT}) using a variable switched-capacitor resistor (VAR SCR) [7] with an impedance of Z_{SCR}=1/2πfC, where f is the clock frequency of the SCR and C is the capacitance of the core capacitors. By sweeping f or varying C the impedance changes and the current in device M_{A}, which is mirrored to M_{B} as I_{DUT} yields I_{DUT}=2πfC·V_{REF1}. The first loop is stabilized by C_{PG}, making V_{PG} its dominant pole. The second loop, controlled by A₁ and device M_{C} (orange) regulates the V_{DS} of the DUT. The third loop, controlled by A₂ (blue), equalizes the drains of devices M_{A} and M_{B} (V_{SC}=V_{PD}) by controlling the gate of DUT and forcing the V_{GS} of the DUT to support the input current. V_{GS} is forwarded to a discrete-time sigma-delta modulator (DT-SDM) analog-to-digital converter (ADC). To handle the kickbacks of the ADC sampling, a source follower (SF) stage is added after A₂. The third loop is stabilized by placing a Miller capacitor, C_{M}, between high impedance nodes V_{N2} and V_{PD}. The second gain stage of this loop is the NMOS DUT itself, with the lowest DUT current being the worst stability corner. The A₁ loop is stabilized by capacitor C_{N1}. The three loops will not negatively interact if they are all stable. V_{REF1} and V_{REF2} are generated using resistor ladders from V_{CC}. The components of FIG. 4A are re-used for the PMOS measurement by applying some switches resulting in the configuration of FIG. 4B. Very Wide Common-mode Amplifiers (VCDA) [9] were used for NMOS and PMOS configurations, which had nominal gain of 56 dB.

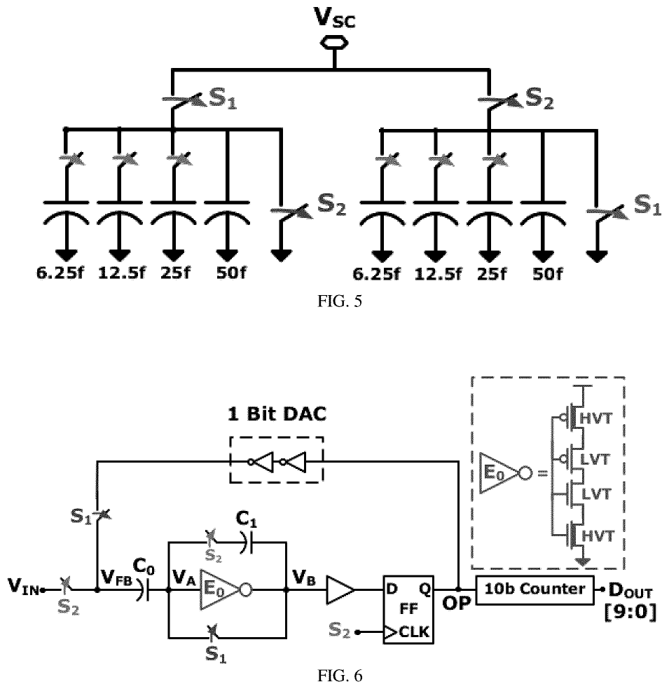

Varying I_{DUT} is done by changing the clock frequency and by varying the core capacitance in the SCR. The implementation of the variable SCR is shown in FIG. 5, where the core capacitors are charged and discharged in an interleaving manner with phases S₁ and S₂, and the capacitance can be selected by a binary code with a step of 6.25 fF. An RC filter (R=178 kΩ, C=680 fF) suppresses the ripple of the SCR before entering A₂. The DT-SDM ADC schematic is shown in FIG. 6. A single stage is used with a 1-bit DAC and flip-flop quantizer. The inverter utilizes low and high V_{TH} (LVT, HVT) cascodes for higher gain [10]. The SDM clock frequency was 50 MHz, which enabled a 10-bit conversion in 20.5 μs.

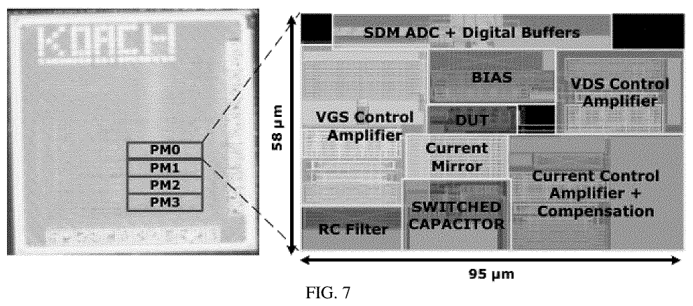

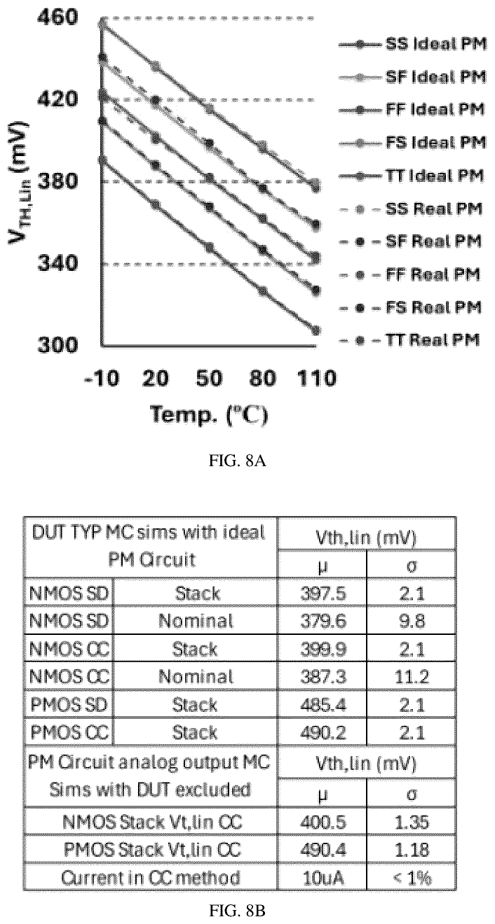

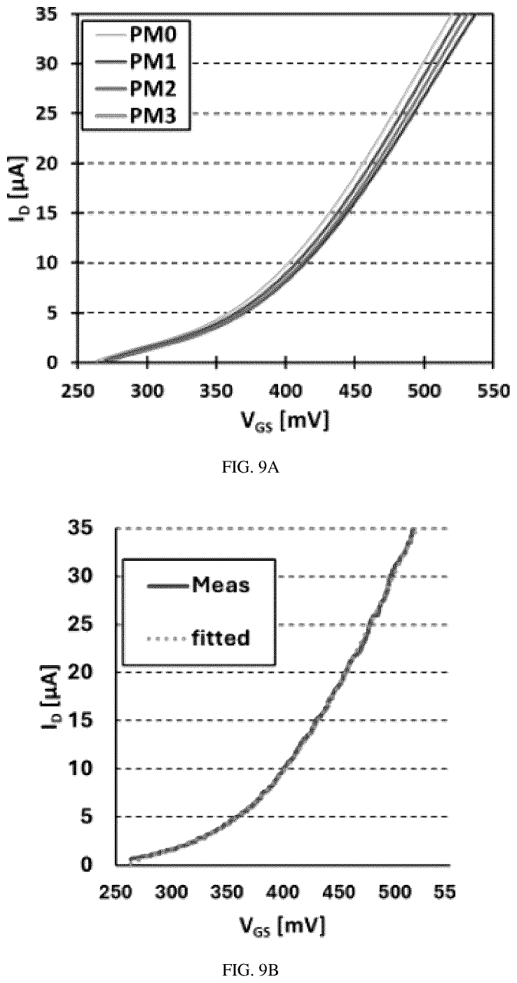

The PM was fabricated in a 28 nm CMOS process. A chip micrograph and layout that occupies 5510 μm² are shown in FIG. 7. Four identical PMs were fabricated on a single die. A total of 12 PMs were measured from multiple dies both in the edge of the linear region (V_{DS}=100 mV) and in saturation (V_{DS}=600 mV). FIG. 8A shows a simulated V_{TH,LIN} of the NMOS stack using the SD method for five corners. This is compared to the DUT driven by ideal elements which form an ideal PM. It is assumed that the temperature is known during the DUT measurement. This demonstrates the accuracy of the circuit across corners. FIG. 8B shows Monte Carlo (MC) simulations of the DUTs with an idealized PM, as well the PM circuit with the DUT excluded from the simulation. The worst case variation occurs in V_{TH,LIN} since it is most sensitive to V_{DS}. FIG. 9 features a polynomial fit of the measured I-V curves extracted from the V_{GS} measurements of the NMOS stacked DUTs in the linear region of one chip. The current is estimated based on the simulations of the frequency and capacitance values, while V_{GS} in the x-axis is the actual measurement. These curves are fit to a polynomial to enable the SD V_{TH} calculation and reduce measurement noise [6].

### EXPERIMENTAL RESULTS

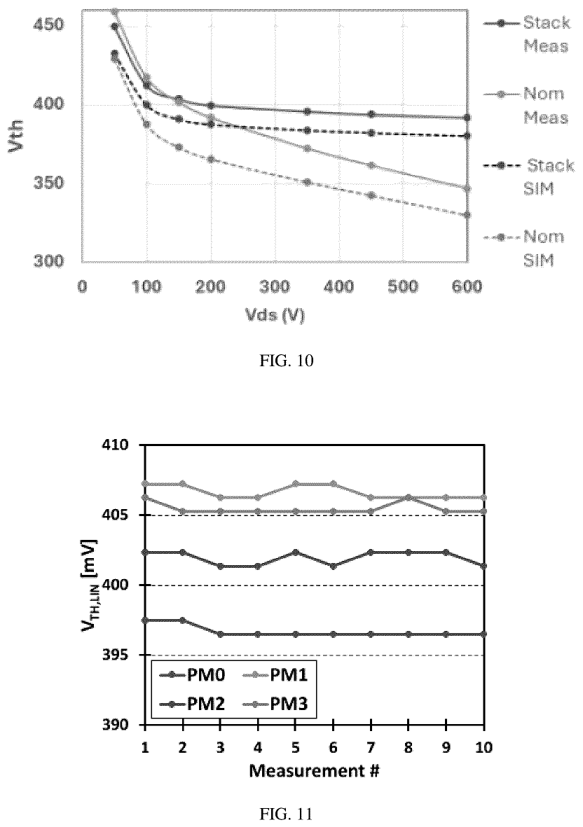

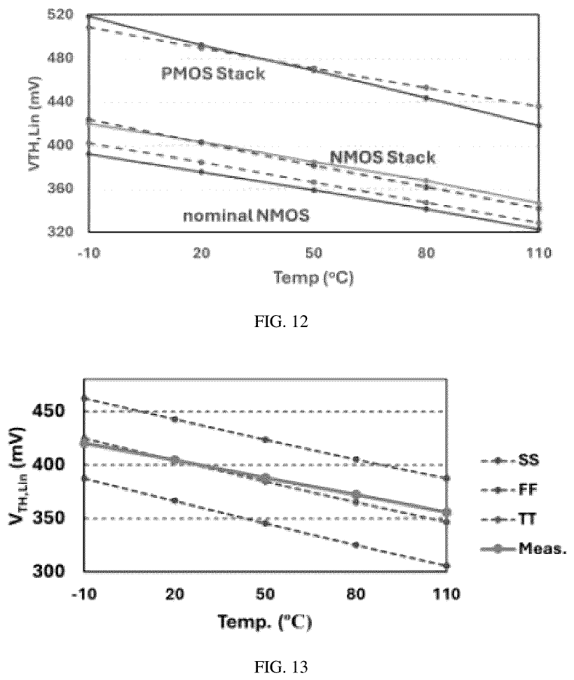

FIG. 10 depicts both simulated and measured V_{TH} using the CC method for nominal and stacked NMOS DUTs when sweeping V_{DS}. The V_{TH} decreases with increased V_{DS} between the linear and saturation regions as the V_{GS} increases to support the CC current in the linear region. Also, the nominal device, V_{TH,SAT} decreases with increasing V_{DS}, likely due to the drain induced barrier lowering (DIBL) effect, as expected in a short channel device. FIG. 11 shows repeated room temperature measurements of V_{TH,LIN} of the NMOS Stack DUT using SD in four PMs, showing repeatability of 1 LSB (least significant bit) (1 mV). An SD measurement of V_{TH,LIN} versus temperature for all DUT types is shown in FIG. 12. In the linear region the stack and nominal devices have a similar V_{TH}, but the PMOS has a higher V_{TH} value which is consistent with simulations. FIG. 13 shows the measured and simulated V_{TH,LIN} versus temperature using the CC method of the stacked NMOS DUT.

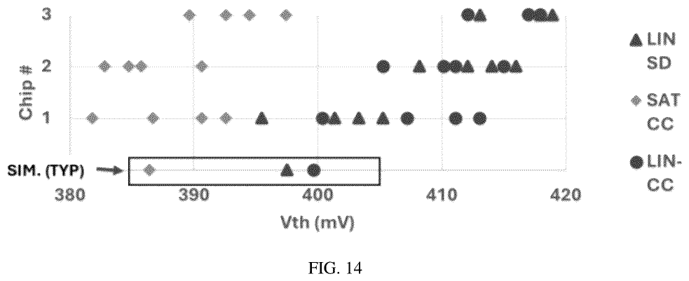

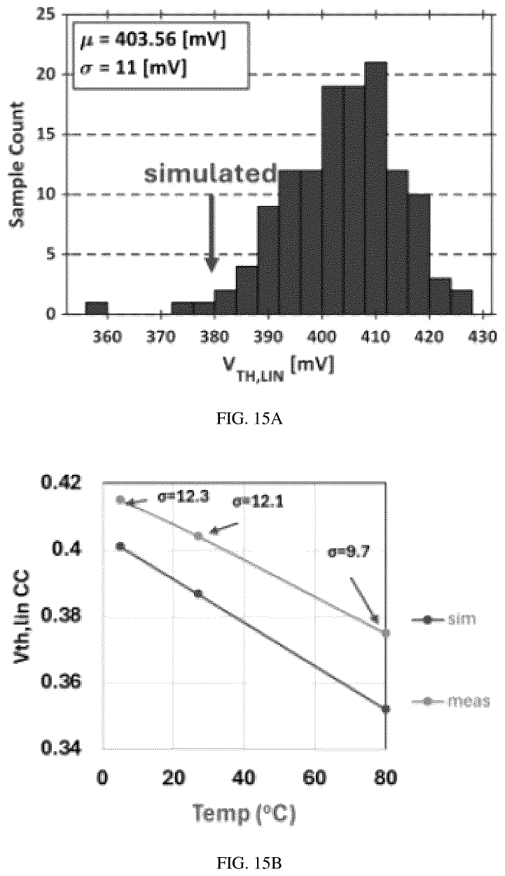

FIG. 14 shows room temperature measurement of V_{TH,LIN} and V_{TH,SAT} of NMOS stacks using CC and SD methods on three chips. There appears to be some systematic variation between the chips, as would be expected, and the measured V_{TH}'S are close to the typical corner. The sigma variation within each chip is between 3.4-4.1 mV for the different methods. This can be improved by applying DC chopping (also known as dynamic element matching) methods to the amplifiers and current sources of the PM and taking several measurements. One of the benefits of using a fully integrated PM is the ability to measure local mismatch. FIG. 15A shows the measured mismatch of V_{TH,LIN} for 128 nominal NMOS devices using the SD method at room temperature. FIG. 15B shows V_{TH,LIN} of the nominal NMOS of a single chip (32 DUTs) vs. temperature. The measured V_{TH}'s are 15-20 mV higher than the typical corner. This could be due to systematic variations across the wafer. The DUT V_{TH} variations are similar to those expected from simulations (FIG. 8B). For this demonstration 8 nominal DUTs were placed in each PM, but this number can be increased.

### CONCLUSIONS

TABLE 1

| Reference | [4] | [3] | [8] | [5] | [7] | This Work |
|---|---|---|---|---|---|---|
| Technology (nm) | 65 | 65 | 1200 | 180 | 65 | 28 |
| Functions | OK V_{TH} Ref | OK V_{TH} Ref | V_{TH} | V_{TH} | V_{TH} | V_{TH} |
| | Generator | Generator | Extractor | Extractor | Extractor | Extractor |
| | | | | | (Diode) | ( [symbol] ) |
| V_{TH} Extraction Method | V_{OS} | V_{OS} | LE | V_{OS} | CC | SD/I-V/CC |
| Random Variation | No | No | No | No | No | Yes |
| Measurement | | | | | | |
| V_{OS} Regulation | No | No | No | No | No | Yes |
| Devices | N | N | N/P | N | N/P + Stack | N/P + Stack |
| Temp Range (° C.) | −40 to 90 | −40 to 80 | −50 to 100 | −40 to 125 | −10 to 110 | −10 to 110 |
| Supply Voltage Range (V) | 0.75-1.2 | 0.75-1.2 | 3.8-6.5 | 0.6-1.8 | 1.1-1.5 | 1.35-1.65 |
| Extractor [symbol] Variation | 16 | 15 | NA | 5.2 | 3.95 | 4.17 |
| including DUT (mV) | | | | | | |
| Units Measured | 15 | 15 | 1 | Simulated | 20 | 12 |
| Output Type | Analog | Analog | Analog | Analog | Digital | Digital |
| Power (μW) | 0.29 | 2.6 | NA | 0.023 | 185 | 209* |
| Area (μm²) | 19760 | 76900 | NA | NA | 5800 | 5510 |

*Simulated in CC current [symbol]
indicates data missing or illegible when filed

Table 1 shows a comparison of the PM according to the present invention with various prior art PMs which use different extraction methods. The PM of the invention is fully integrated and can accurately extract I-V curves from the DUT. Then V_{TH} can be measured using the quick CC method, or the gold-standard SD method [6]. In the SD method, the inflection point of the I-V curve is of interest, so the absolute accuracy of the current is less important. Once V_{TH} is measured initially by the SD method in testing, the current in the CC method can be adjusted to give similar results for quick measurements over the lifetime of the product, as was done for V_{TH,LIN} as described above. Furthermore, in the PM of an embodiment of the invention the V_{DS} of the DUT is regulated, which enables extracting V_{TH,LIN} and V_{TH,SAT}, which was not done in the prior art [5,7]. Once an I-V curve is generated, and the V_{DS} of the DUT is controlled, other parameters such as Si mobility (speed at which electrons or holes move through the silicon substrate) can be estimated by this circuit and various V_{TH} extraction methods could be compared on different device types. Random variation was also measured by extracting V_{TH} from many nominal DUTs which was not implemented in the prior art. All these features could be used as part of a SoC which could extract S₁ parameters during real time operation to optimize energy efficiency of the system. The circuit could be used as a DFT circuit or sampled occasionally during operation, so the power is not an important parameter. Device measurements are generally in the scribe lines and are invisible to the product developer. The PM of the invention allows the customer to measure V_{TH} using several methods. It also helps the fabrication, since in-die V_{TH} measurements can be done on the product die itself.

### REFERENCES

[1] R. G. Dreslinski et al., “Near-Threshold Computing: Reclaiming Moore's Law Through Energy Efficient Integrated Circuits,” Proceedings of the IEEE, vol. 98, no. 2, pp. 253-266, February 2010.
[2] E. Beigne et al., “A 460 MHz at 397 mV, 2.6 GHz at 1.3 V, 32 bits VLIW DSP Embedding F MAX Tracking,” IEEE J Solid-State Circuits, vol. 50, no. 1, pp. 125-136, January 2015.
[3] D. Wang, X. L. Tan, and P. K. Chan, “A Performance-Aware MOSFET Threshold Voltage Measurement Circuit in a 65-nm CMOS,” IEEE Trans Very Large Scale Integr VLSI Syst, vol. 24, no. 4, pp. 1430-1440, April 2016.
[4] X. L. Tan, P. K. Chan, and U. Dasgupta, “A Sub-1-V 65-nm MOS Threshold Monitoring-Based Voltage Reference,” IEEE Trans Very Large Scale Integr VLSI Syst, vol. 23, no. 10, pp. 2317-2321, October 2015.
[5] O. E. Mattia, H. Klimach, S. Bampi, and M. Schneider, “0.7 V supply selfbiased nanoWatt MOS-only threshold voltage monitor,” in 2015 IEEE International Symposium on Circuits and Systems (ISCAS), IEEE, May 2015, pp. 497-500.
[6] A. Ortiz-Conde et al., “Revisiting MOSFET threshold voltage extraction methods,” Microelectronics Reliability, vol. 53, no. 1, pp. 90-104, January 2013.
[7] L. Lisha, O. Bass, and J. Shor, “A 5800 μm2 Process Monitor Circuit for Measurement of in-Die Variation of Vth in 65 nm,” IEEE Transactions on Circuits and Systems II: Express Briefs, vol. 68, no. 3, pp. 863-867, March 2021.
[8] S. K. Hoon and U. Cilingiroglu, “An optimally self-biased threshold voltage extractor,” in ICECS 2001. 8th IEEE International Conference on Electronics, Circuits and Systems (Cat. No. 01EX483), IEEE, pp. 19-22.
[9] M. Bazes, “Two novel fully complementary self-biased CMOS differential amplifiers,” in IEEE Journal of Solid-State Circuits, vol. 26, no. 2, pp. 165-168, February 1991.
[10] A. Feldman, O. Nechushtan, and J. Shor, “Voltage Level Detection for Near-VTH Computing,” IEEE Journal of Solid-State Circuits, vol. 59, no. 6, pp. 1847-1857, June 2024.

What is claimed is:

1. A process monitor for a transistor device comprising:
a current source circuitry configured to provide an input current (I_{IN}) to a drain of at least one Device Under Test (DUT), which comprises an NMOS (n-type metal oxide semiconductor) or a PMOS (n-type metal oxide semiconductor);
a drain-source voltage regulation circuitry configured to regulate a drain-source voltage (referred to as V_{DS} for NMOS, V_{SD} for PMOS) of said at least one DUT;
a gate-source voltage regulation circuitry configured to regulate a gate-source voltage (V_{GS}) of said at least one DUT versus said input current so that said drain-source voltage remains constant and said at least one DUT is in a linear region or in a saturation region or between the linear and saturation regions; and
a measurement circuitry configured to measure said gate-source voltage to derive therefrom an operational parameter of said transistor device.

2. The process monitor according to claim 1, wherein said operational parameter is a threshold voltage of said at least one DUT.

3. The process monitor according to claim 1, wherein said operational parameter is a threshold voltage of said at least one DUT in said linear region.

4. The process monitor according to claim 1, wherein said operational parameter is a threshold voltage of said at least one DUT in said saturation region.

5. The process monitor according to claim 1, wherein said operational parameter is a mobility of a silicon substrate of said at least one DUT.

6. The process monitor according to claim 1, wherein said operational parameter is a random variation of said at least one DUT.

7. The process monitor according to claim 1, wherein said current source circuitry comprises a switched capacitor circuit.

8. The process monitor according to claim 7, wherein said switched capacitor circuit comprises a reference voltage which is applied to at least one switching capacitor to generate said input current which equals C*V*F, where C is capacitance of said at least one switching capacitor, V is said reference voltage and F is a switching frequency, and said input current is mirrored to said at least one DUT.

9. The process monitor according to claim 8, wherein said current source circuitry is configured to vary said input current by changing a clock frequency and a core capacitance in said switched capacitor circuit.

10. The process monitor according to claim 1, wherein said at least one DUT comprises more than one DUT, and further comprising a multiplexer configured to select which DUT is to be measured from said more than one DUT.

11. The process monitor according to claim 1, wherein said gate-source voltage is forwarded to a discrete-time sigma-delta modulator (DT-SDM) analog-to-digital converter.
